(19) United States
(12) Patent Application Publication
(10) Pub. No.: US 2026/0074563 A1
(43) Pub. Date: Mar. 12, 2026

(54) WIRELESS CHARGING DEVICE

(71) Applicants: INVENTEC (PUDONG) TECHNOLOGY CORPORATION, Shanghai (CN); INVENTEC CORPORATION, Taipei City (TW)

(72) Inventor: Chi-Cheng HSIAO, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 18/944,961

(22) Filed: Nov. 12, 2024

(30) Foreign Application Priority Data
Sep. 6, 2024 (CN) 202411252862.3

(51) Int. Cl. H02J 50/00; H02J 50/10; H05K 7/20

(52) U.S. Cl. CPC H02J 50/005; H02J 50/10; H05K 7/20909

(57) ABSTRACT

A wireless charging device includes a casing, a wireless charging module and a fan. The casing includes a support surface, an air guiding recess, a first air inlet, an interior space and an air outlet. The support surface supports an electronic device, the air guiding recess is recessed from the support surface, the first air inlet is located in the air guiding recess and communicates with the interior space, and the air outlet communicates with the interior space. The wireless charging module is disposed in the interior space and configured to correspond to the electronic device. The fan is disposed on the casing and corresponds to the air outlet. The fan is configured to suck external air into the interior space through the first air inlet from the air guiding recess and blow air in the interior space out of the wireless charging device through the air outlet.

### CROSS-REFERENCE TO RELATED APPLICATIONS

This non-provisional application claims priority under 35 U.S.C. § 119(a) on Patent Application No(s). 202411252862.3 filed in China, on Sep. 6, 2024, the entire contents of which are hereby incorporated by reference.

### BACKGROUND OF THE INVENTION

### Technical Field of the Invention

The invention relates to a charging device, more particularly to a wireless charging device.

### Description of the Related Art

As the development and progress of technology, mobile devices, such as smart phones or tablet computers, can be connected to the vehicle system through application programs (e.g., CarPlay). In order to let users not to worry about the power consumption of mobile devices, wireless chargers are further applied to the vehicles so that the mobile devices can be connected to the vehicle system through the application programs while placed on the wireless chargers for charging.

When a mobile device is placed on a wireless charger for charging, the wireless charger and the mobile device both generate heat. Under the influence of these two kinds of heat, the charging efficiency of the wireless charger may be reduced. Therefore, how to solve the aforementioned issue is one of the topics in this field.

### SUMMARY OF THE INVENTION

The invention provides a wireless charging device which is capable of preventing heat generated by itself and the mobile device from adversely affecting the charging efficiency.

One embodiment of the invention provides a wireless charging device. The wireless charging device is configured to charge an electronic device. The wireless charging device includes a casing, a wireless charging module and a fan. The casing includes a support surface, an air guiding recess, a first air inlet, an interior space and an air outlet. The support surface is configured to support the electronic device, the air guiding recess is recessed from the support surface, the first air inlet is located in the air guiding recess and communicates with the interior space, and the air outlet communicates with the interior space. The wireless charging module is disposed in the interior space and configured to correspond to the electronic device. The fan is disposed on the casing and corresponds to the air outlet. The fan is configured to suck external air into the interior space through the first air inlet from the air guiding recess and blow air in the interior space out of the wireless charging device through the air outlet.

According to the wireless charging device as discussed in the above embodiment, the air guiding recess of the casing is recessed from the support surface, the first air inlet is located in the air guiding recess and communicates with the interior space, the wireless charging module is disposed in the interior space, and the fan is disposed on the casing and corresponds to the air outlet, which enables the fan to suck external air into the interior space through the first air inlets from the air guiding recess, and blows air in the interior space out of the wireless charging device from the air outlet. As a result, during the operation of the fan, before external air enters into the interior space through the air guiding recess and the first air inlet, external air can absorb heat generated by the electronic device, and the fan can blow air in the interior space which has already absorbed heat generated by the electronic device and the wireless charging module out of the wireless charging device, and thus the charging efficiency of the wireless charging device can be prevented from being adversely affected by heat generated by the wireless charging module and the electronic device.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a perspective view of a wireless charging device and an electronic device according to one embodiment of the invention;

FIG. 2 is an exploded view of the wireless charging device in FIG. 1;

FIG. 3 is a cross-sectional view of the wireless charging device in FIG. 1;

FIG. 4 is another cross-sectional view of the wireless charging device in FIG. 1; and

FIG. 5 is a top view of the wireless charging device in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present invention, such as technical and scientific terms, have its own meanings and can be comprehended by those skilled in the art, unless the terms are additionally defined in the present invention. That is, the terms used in the following paragraphs should be read on the meaning commonly used in the related fields and will not be overly explained, unless the terms have a specific meaning in the present invention.

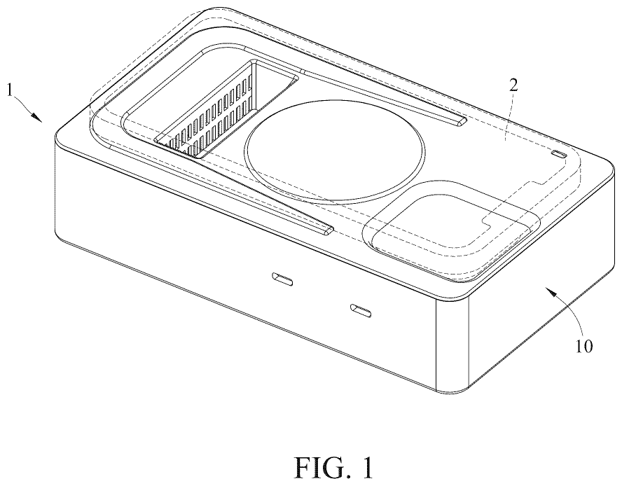

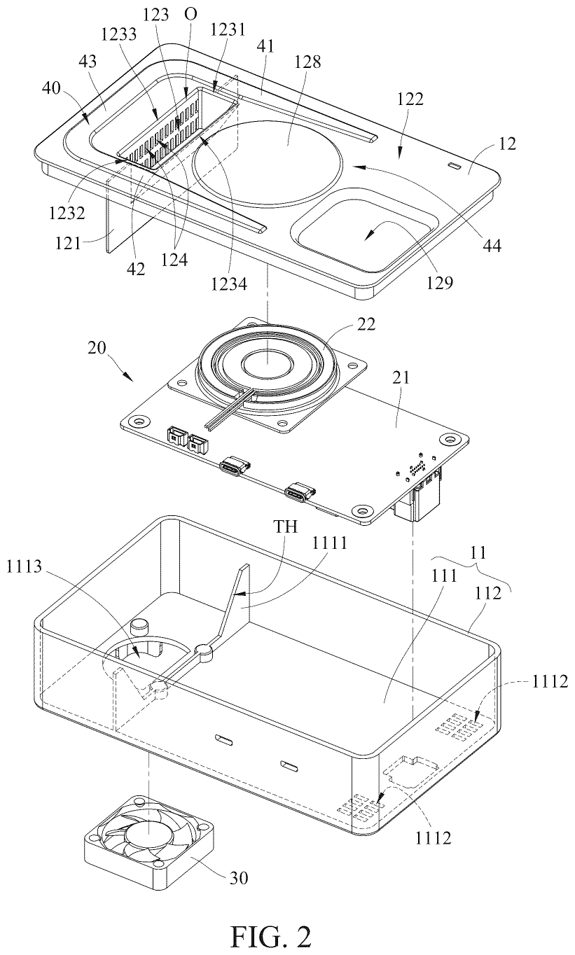

Referring to FIGS. 1 and 2, FIG. 1 is a perspective view of a wireless charging device and an electronic device according to one embodiment of the invention, and FIG. 2 is an exploded view of the wireless charging device in FIG. 1.

In this embodiment, the wireless charging device 1 is configured to charge an electronic device 2. The electronic device 2 is, for example, a smart phone. The wireless charging device 1 includes a casing 10, a wireless charging module 20 and a fan 30.

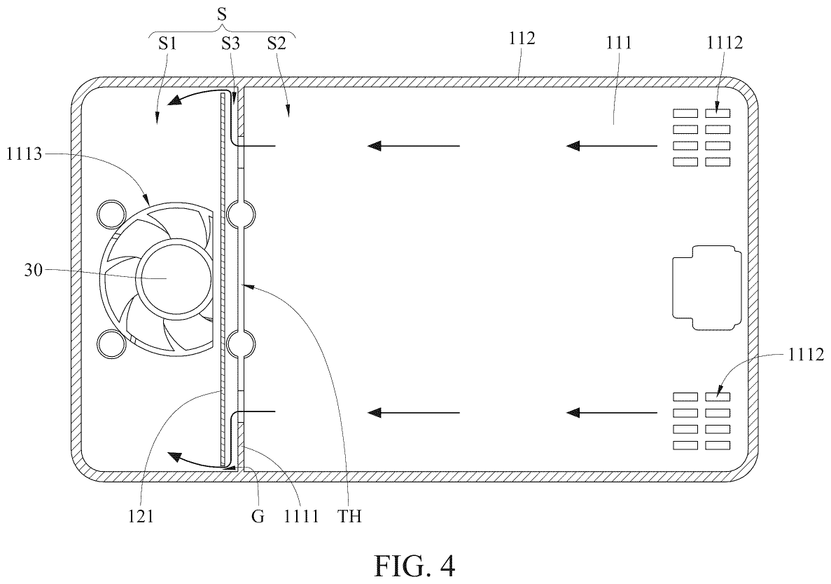

Then, referring to FIGS. 2 to 4, FIG. 3 is a cross-sectional view of the wireless charging device in FIG. 1, and FIG. 4 is another cross-sectional view of the wireless charging device in FIG. 1.

The casing 10 includes a base 11 and a cover 12. The base 11 includes a bottom portion 111 and a surrounding wall portion 112. The surrounding wall portion 112 is connected to a periphery of the bottom portion 111, and the cover 12 is mounted on the surrounding wall portion 112. The bottom portion 111, the surrounding wall portion 112 and the cover 12 together form an interior space S. The bottom portion 111 includes a first partition structure 1111, the first partition structure 1111 is located in the interior space S and extends towards the cover 12. The cover 12 includes a second partition structure 121, and the second partition structure 121 is located in the interior space S and extends towards the bottom portion 111. The second partition structure 121 and the first partition structure 1111 are spaced apart from each other. The first partition structure 1111 and the second partition structure 121 divides the interior space S into a first chamber S1, a second chamber S2 and a communication channel S3, where the communication channel S3 is located between the first chamber S1 and the second chamber S2, and communicates with the first chamber S1 and the second chamber S2. For example, the first partition structure 1111 includes a communication hole TH, different sides of the second partition structure 121 are spaced apart from the bottom portion 111 and the surrounding wall portion 112 so as to form a gap G. The second chamber S2 communicates with the first chamber S1 through the communication hole TH, the communication channel S3 and the gap G.

In this embodiment, the cover 12 further includes a support surface 122, an air guiding recess 123 and a plurality of first air inlets 124. The support surface 122 faces away from the interior space S and is configured to support the electronic device 2. The air guiding recess 123 is recessed from the support surface 122, and an opening O of the air guiding recess 123 located close to the support surface 122, for example, has a rectangular shape. The opening O of the air guiding recess 123 has a first side 1231, a second side 1232, a third side 1233 and a fourth side 1234. The first side 1231 is located opposite to the second side 1232, and the third side 1233 is located opposite to the fourth side 1234. A width of the air guiding recess 123 gradually decreases along a direction away from the support surface 122. For example, the cover 12 further includes an inner bottom surface 125, a first inner side surface 126 and a second inner side surface 127, the inner bottom surface 125 is located at a bottom of the air guiding recess 123, and the first inner side surface 126 and the second inner side surface 127 are located at two opposite sides of the air guiding recess 123 in a width direction of the air guiding recess 123. The first inner side surface 126 is connected to the support surface 122 and one side of the inner bottom surface 125, and the second inner side surface 127 is connected to the support surface 122 and another side of the inner bottom surface 125. The first inner side surface 126 is perpendicular to the inner bottom surface 125, the second inner side surface 127 is inclined to the inner bottom surface 125, and a distance T1 between one side of the second inner side surface 127 located closer to the support surface 122 and the first inner side surface 126 is greater than a distance T2 between another side of the second inner side surface 127 located closer to the inner bottom surface 125 and the first inner side surface 126. The first air inlets 124 of the cover 12 are located at the first inner side surface 126 and directly communicate with the first chamber S1.

In this embodiment, the bottom portion 111 of the base 11 further includes a plurality of second air inlets 1112 and an air outlet 1113. The second air inlets 1112 directly communicate with the second chamber S2, and the air outlet 1113 directly communicates with the first chamber S1.

Note that the quantities of the first air inlets 124 and the second air inlets 1112 are not restricted in the invention and may be modified to be one in some other embodiments.

In this embodiment, the cover 12 may further include a support protrusion 128 and an accommodation recess 129. The support protrusion 128 protrudes from the support surface 122, and the support protrusion 128 is located aside the fourth side 1234 of the opening O of the air guiding recess 123 and is configured to support the electronic device 2, such that a gap is formed between the electronic device 2 and the support surface 122. The accommodation recess 129 is recessed from the support surface 122 and located at one side of the support protrusion 128 located farther away from the air guiding recess 123. The accommodation recess 129 is configured to accommodate a lens of the electronic device 2. Note that the support protrusion 128 and the accommodation recess 129 are optional structures and may be omitted in some other embodiments.

The wireless charging module 20 is, for example but not limited to, a Qi 2.0 wireless charging module. The wireless charging module 20 is disposed in the second chamber S2 and includes a circuit board 21 and a coil assembly 22 electrically connected to the circuit board 21. The coil assembly 22 corresponds to the support protrusion 128 of the cover 12 and is configured to charge the electronic device 2 in a wireless manner.

In this embodiment, the base 11 may further include a holding structure 113. The holding structure 113 is connected to a surface of the bottom portion 111 facing away from the interior space S. The holding structure 113 is located around the air outlet 1113 of the bottom portion 111, and includes a fan accommodation space 1131. The fan 30 is mounted in the fan accommodation space 1131, and an air inlet side of the fan 30 corresponds to the air outlet 1113 of the bottom portion 111.

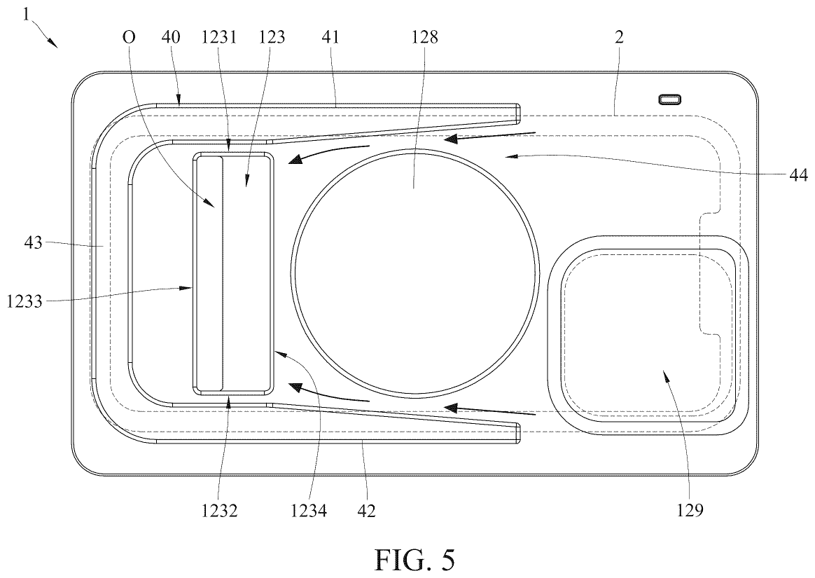

Then, referring to FIGS. 2 and 5, FIG. 5 is a top view of the wireless charging device in FIG. 1.

In this embodiment, the wireless charging device 1 may further include a support pad 40, and the support pad 40 is disposed on the support surface 122 of the cover 12. The support pad 40 is configured to support the electronic device 2 for producing a gap between the electronic device 2 and the support surface 122. The support pad 40 is a U-shaped structure and includes a first support portion 41, a second support portion 42 and a third support portion 43 connected to one another. The first support portion 41, the second support portion 42 and the third support portion 43 are respectively located aside the first side 1231, the second side 1232 and the third side 1233 of the opening O of the air guiding recess 123, and the first support portion 41 and the second support portion 42 further extend to two opposite sides of the support protrusion 128. An air guiding opening 44 is formed between sides of the first support portion 41 and the second support portion 42 located farther away from the third support portion 43. The air guiding recess 123 is located between the air guiding opening 44 and the third support portion 43, and a width of the air guiding opening 44 gradually decreases along a direction towards the air guiding recess 123.

Then, the following paragraphs will describe an airflow produced during the operation of the fan 30, where the direction of the airflow is indicated by arrows. Firstly, as shown in FIG. 5, during the operation of the fan 30, the fan 30 drives external air to flow towards the air guiding recess 123 through the air guiding opening 44 and the back of the electronic device 2. As a result, air passing through the back of the electronic device 2 can absorb heat generated by the electronic device 2 and take it away.

In this embodiment, the width of the air guiding opening 44 gradually decreases along the direction towards the air guiding recess 123, which guides air towards the air guiding recess 123. In addition, the support pad 40 is the U-shaped structure, and the first support portion 41, the second support portion 42 and the third support portion 43 are respectively located aside the first side 1231, the second side 1232 and the third side 1233 of the opening O of the air guiding recess 123, which can concentrate air towards the air guiding recess 123 for ensuring a sufficient amount of air entering into the air guiding recess 123.

Note that when the desired amount of air entering into the air guiding recess 123 is fewer, the width of the air guiding opening may be a constant along the direction towards the air guiding recess, and the support pad may be a structure with another shape in some other embodiments. In another embodiment, the support pad may be omitted.

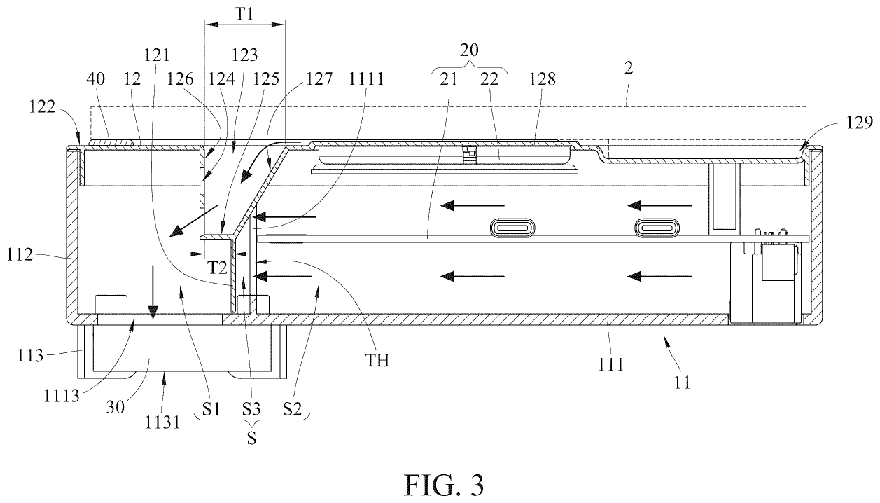

Then, as shown in FIG. 3, air enters into the first chamber S1 through the air guiding recess 123 and the first air inlets 124, and then passes through the air outlet 1113 and is extracted out of the wireless charging device 1 by the fan 30.

In this embodiment, the air guiding recess 123 can reduce the flowing resistance of air entering into the first chamber S1 so as to enable air to smoothly enter into the first chamber S1. In addition, the width of the air guiding recess 123 gradually decreases along the direction away from the support surface 122, which enables air to flow into the first chamber S1 more smoothly.

Note that the width of the air guiding recess 123 is not restricted to gradually decreasing along the direction away from the support surface 122. When other structures are provided to reduce the flowing resistance of air entering into the first chamber, the width of the air guiding recess may be a constant or may gradually increase along the direction away from the support surface.

On the other hand, as shown in FIGS. 3 and 4, during the operation of the fan 30, air can enter into the second chamber S2 from the second air inlets 1112 of the bottom portion 111 so as to absorb heat generated by electronic components on the circuit board 21 and the coil assembly 22. Then, air enters into the first chamber S1 through the communication hole TH, the communication channel S3 and the gap G, and then passes through the air outlet 1113 and is extracted out of the wireless charging device 1 by the fan 30.

As a result, during the operation of the fan 30, before external air enters into the interior space S through the air guiding recess 123 and the first air inlets 124, external air can absorb heat generated by the electronic device 2, and the fan 30 can blow air in the interior space S which has already absorbed heat generated by the electronic device 2 and the wireless charging module 20 out of the wireless charging device 1, and thus the charging efficiency of the wireless charging device 1 can be prevented from being adversely affected by heat generated by the wireless charging module 20 and the electronic device 2.

In this embodiment, the first partition structure 1111 of the bottom portion 111 and the second partition structure 121 of the cover 12 can prevent liquid entering into the first chamber S1 through the air guiding recess 123 and the first air inlets 124 from being slapped by a fan blade of the fan 30 so as to splash into the second chamber S2, thereby ensuring that the wireless charging module 20 in the second chamber S2 will not be damaged by liquid.

Note that the first partition structure 1111 of the bottom portion 111 and the second partition structure 121 of the cover 12 are optional structures and may be omitted in some other embodiments, and other structures may be provided to prevent liquid entering into the interior space from reaching the wireless charging module. In such a case, the second air inlets are optional structures and may be omitted.

In addition, in this embodiment, the fan 30 is disposed on the surface of the bottom portion 111 facing away from the interior space S via the holding structure 113; that is, the fan 30 is disposed outside the interior space S, which can prevent the fan 30 from interfering with the flowing of air in the interior space S.

Note that the holding structure 113 is an optional structure and may be omitted in some other embodiments. In such a case, the fan can be fixed on the surface of the bottom portion facing away from the interior space via screws merely. In addition, the fan is not restricted to being disposed outside the interior space. When the fan would not interfere with the flowing of air in the interior space, the fan may be disposed in the interior space in some other embodiments.

According to the wireless charging device as discussed in the above embodiment, the air guiding recess of the casing is recessed from the support surface, the first air inlets are located in the air guiding recess and communicate with the interior space, the wireless charging module is disposed in the interior space, and the fan is disposed on the casing and corresponds to the air outlet, which enables the fan to suck external air into the interior space through the first air inlets from the air guiding recess, and blows air in the interior space out of the wireless charging device from the air outlet. As a result, during the operation of the fan, before external air enters into the interior space through the air guiding recess and the first air inlets, external air can absorb heat generated by the electronic device, and the fan can blow air in the interior space which has already absorbed heat generated by the electronic device and the wireless charging module out of the wireless charging device, and thus the charging efficiency of the wireless charging device can be prevented from being adversely affected by heat generated by the wireless charging module and the electronic device.

In addition, the width of the air guiding opening of the support pad gradually decreases along the direction towards the air guiding recess, which guides air towards the air guiding recess. Furthermore, the support pad is the U-shaped structure, and the first support portion, the second support portion and the third support portion are respectively located aside the first side, the second side and the third side of the opening of the air guiding recess, which can concentrate air towards the air guiding recess for ensuring a sufficient amount of air entering into the air guiding recess.

Moreover, the air guiding recess can reduce the flowing resistance of air entering into the first chamber so as to enable air to smoothly enter into the first chamber. In addition, the width of the air guiding recess gradually decreases along the direction away from the support surface, which enables air to flow into the first chamber more smoothly.

On the other hand, the first partition structure of the bottom portion and the second partition structure of the cover can prevent liquid entering into the first chamber through the air guiding recess and the first air inlets from being slapped by a fan blade of the fan so as to splash into the second chamber, thereby ensuring that the wireless charging module in the second chamber will not be damaged by liquid.

In one embodiment of the invention, the wireless charging device may be applied in a vehicle, such an autonomous vehicle, an electric vehicle or a semi-autonomous vehicle etc.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. A wireless charging device, configured to charge an electronic device, comprising:
a casing, comprising a support surface, an air guiding recess, a first air inlet, an interior space and an air outlet, wherein the support surface is configured to support the electronic device, the air guiding recess is recessed from the support surface, the first air inlet is located in the air guiding recess and communicates with the interior space, and the air outlet communicates with the interior space;
a wireless charging module, disposed in the interior space and configured to correspond to the electronic device; and
a fan, disposed on the casing and corresponding to the air outlet, wherein the fan is configured to suck external air into the interior space through the first air inlet from the air guiding recess and blow air in the interior space out of the wireless charging device through the air outlet.

2. The wireless charging device according to claim 1, wherein a width of the air guiding recess gradually decreases along a direction away from the support surface.

3. The wireless charging device according to claim 2, wherein the casing comprises an inner bottom surface, a first inner side surface and a second inner side surface, the inner bottom surface is located at a bottom of the air guiding recess, the first inner side surface and the second inner side surface are located at two opposite sides of the air guiding recess in a width direction of the air guiding recess, the first inner side surface is connected to the support surface and one side of the inner bottom surface, the second inner side surface is connected to the support surface and another side of the inner bottom surface, the first inner side surface is perpendicular to the inner bottom surface, the second inner side surface is inclined to the inner bottom surface, and the first air inlet is located at the first inner side surface.

4. The wireless charging device according to claim 1, further comprising a support pad, wherein the support pad is disposed on the support surface and is configured to support the electronic device,

5. The wireless charging device according to claim 4, wherein an opening of the air guiding recess located close to the support surface has a rectangular shape, the opening of the air guiding recess has a first side, a second side, a third side and a fourth side, the first side is located opposite to the second side, the third side is located opposite to the fourth side, the support pad is a U-shaped structure and comprises a first support portion, a second support portion and a third support portion connected to one another, the first support portion, the second support portion and the third support portion are respectively located aside the first side, the second side and the third side of the opening of the air guiding recess.

6. The wireless charging device according to claim 5, wherein an air guiding opening is formed between sides of the first support portion and the second support portion located farther away from the third support portion, the air guiding recess is located between the air guiding opening and the third support portion, and a width of the air guiding opening gradually decreases along a direction towards the air guiding recess.

7. The wireless charging device according to claim 1, wherein the casing comprises a base and a cover, the base comprises a bottom portion and a surrounding wall portion, the surrounding wall portion stands on a periphery of the bottom portion, the cover is mounted on the surrounding wall portion, the cover and the base together form the interior space, the bottom portion comprises a first partition structure and a second air inlet, the first partition structure is located in the interior space and extends towards the cover, the cover comprises a second partition structure, the second partition structure is located in the interior space and extends towards the bottom portion, the second partition structure and the first partition structure are spaced apart from each other, the first partition structure and the second partition structure divides the interior space into a first chamber, a second chamber and a communication channel, the communication channel communicates with the first chamber and the second chamber, the first air inlet and the air outlet directly communicate with the first chamber, the wireless charging module is located in the second chamber, and the second air inlet directly communicates with the second chamber.

8. The wireless charging device according to claim 7, wherein the first partition structure comprises a communication hole, different sides of the second partition structure are respectively spaced apart from the bottom portion and the surrounding wall portion so as to form a gap, the second chamber communicates with the first chamber through the communication hole, the communication channel and the gap.

9. The wireless charging device according to claim 1, wherein the casing further comprises a support protrusion, the support protrusion protrudes from the support surface, the support protrusion is located aside the air guiding recess and is configured to support the electronic device.

10. The wireless charging device according to claim 1, wherein the casing comprising an accommodation recess, the accommodation recess is recessed from the support surface and is configured to accommodate a lens of the electronic device.
